(19) United States
(12) Patent Application Publication
(10) Pub. No.: US 2024/0312831 A1
(43) Pub. Date: Sep. 19, 2024

(54) METHOD FOR PRODUCING A SEMICONDUCTOR STRUCTURE COMPRISING A USEFUL LAYER MADE OF SILICON CARBIDE, WITH IMPROVED ELECTRICAL PROPERTIES

(71) Applicants: SOITEC, BERNIN (FR); COMMISSARIAT A L'ENERGIE ATOMIQUE ET AUX ENERGIES ALTERNATIVES, Paris (FR)

(72) Inventors: Alexis Drouin, Bernin (FR); Gweltaz Gaudin, Bernin (FR); Séverin Rouchier, Bernin (FR); Walter Schwarzenbach, Bernin (FR); Julie Widiez, Paris (FR); Emmanuel Rolland, Paris (FR)

(21) Appl. No.: 18/566,474

(22) PCT Filed: May 25, 2022
(86) PCT No.: PCT/FR2022/051000

§ 371 Date: Dec. 1, 2023

(30) Foreign Application Priority Data
Jun. 3, 2021 (FR) FR2105848

(51) Int. Cl. H01L 21/762; H01L 21/04

(52) U.S. Cl. CPC H01L 21/76254; H01L 21/0445

(57) ABSTRACT

A method for producing a semiconductor structure comprises: a) provision of a monocrystalline silicon carbide donor substrate and a silicon carbide support substrate; b) production of a useful layer to be transferred, comprising—implanting light species in the donor substrate at a front face, so as to form a damage profile, the profile having a main peak of deep-level defects defining a buried brittle plane and a secondary peak of defects defining a damaged surface layer, and—removing the damaged surface layer by chemical etching and/or chemical mechanical polishing of the front face of the donor substrate, so as to form a new front surface of the donor substrate; c) assembly of donor substrate with the support substrate; and d) separation along the buried fragile plane, leading to the transfer of the useful layer onto the support substrate, so as to form the semiconductor structure.

### CROSS-REFERENCE TO RELATED APPLICATIONS

This application is a national phase entry under 35 U.S.C. § 371 of International Patent Application PCT/FR2022/051000, filed May 25, 2022, designating the United States of America and published as International Patent Publication WO 2022/254131 A1 on Dec. 8, 2022, which claims the benefit under Article 8 of the Patent Cooperation Treaty of French Patent Application Serial No. FR2105848, filed Jun. 3, 2021.

### TECHNICAL FIELD

The present disclosure relates to the field of semiconductor materials for microelectronic components. In particular, it relates to a process for fabricating a semiconductor structure comprising a working layer made of monocrystalline silicon carbide and transferred onto a carrier substrate made of silicon carbide, via a bonding interface. The method makes it possible to improve the electrical properties of the working layer, as well as those of the semiconductor structure, when vertical electrical conduction is desired.

### BACKGROUND

It is common practice to form a semiconductor structure by moving a semiconductor working layer, of low thickness and of high crystal quality, onto a semiconductor carrier substrate that is advantageously of lower crystal quality. One well-known thin-layer transfer solution is the SMART CUT® process, based on implanting light species and on joining by means of molecular adhesion at a bonding interface. The light species are conventionally chosen from among hydrogen or helium ions or a combination of these two species. Direct bonding by means of molecular adhesion can be obtained by means of various approaches, at ambient temperature or at temperature, under an ambient or controlled atmosphere, notably in a vacuum, by applying pressure to the substrates after bringing their faces to be joined into close contact or simply by means of localized initiation of a bonding wave when the faces to be joined are arranged facing one another. The various direct bonding approaches can also be distinguished by means of the preparatory treatment of the surfaces to be joined, carried out just before joining. Dry or wet chemical cleaning, surface activation by means of plasma or by means of atomic bombardment (for example, SAB (surface activated bonding), ADB (atomic diffusion bonding), etc.), mechanical or chemical-mechanical smoothing of the surfaces or indeed depositing additional layers that promote bonding, can be applied to one or both substrates to be joined.

After transferring the working layer onto the carrier substrate, it is also common practice to apply annealing at high, or even at very high temperatures, to the semiconductor structure, so as to restore the structural and electrical qualities of the working layer and of the bonding interface. It is also known practice to perform heat smoothing treatments or smoothing treatments based on chemical-mechanical polishing, in order to obtain low surface roughness on the free face of the transferred working layer, which is intended to accommodate microelectronic components.

Notably in the field of power electronics, excellent electrical conductivity of the working layer is expected. It can furthermore be advantageous to form a semiconductor structure guaranteeing good electrical conduction between the working layer and the carrier substrate, so as to allow vertical components to be created.

For example, in the case of a semiconductor structure comprising a working layer made of monocrystalline silicon carbide and a carrier substrate made of lower-quality (monocrystalline or polycrystalline) silicon carbide, the electrical characteristics of the working layer are expected to follow Ohm's law, the resistivity of the layer being defined by its level of doping. In order to be compatible with vertical components, vertical electrical conduction, that is to say involving crossing the bonding interface, is expected to be operational: namely, as low as possible a resistivity of the bonding interface, preferably less than 1 mohm.cm², or even less than 0.1 mohm.cm², and an ohmic I(V) (current as a function of voltage) characteristic.

Transferring a working layer made of monocrystalline silicon carbide, onto a carrier substrate also made of monocrystalline silicon carbide, via an intermediate metal layer, by means of the SMART CUT® process with a final restorative annealing, applied to the semiconductor structure, performed in the 1300° C.-1700° C. temperature range, is not enough to obtain the previously mentioned electrical characteristics, as is apparent in FIG. 4, Panel (a): the I(V) curve, which is representative of the electrical properties of the working layer and of the vertical electrical conduction (across the bonding interface) of the semiconductor structure, does not meet the objective of ohmic behavior.

Of course, an annealing at higher temperatures, typically of more than 1800° C., could partially improve the electrical characteristics of the working layer and of the semiconductor structure, but such a treatment is particularly onerous to implement and can furthermore cause other types of adverse crystal defects, notably step bunching, which require additional steps of protecting the surface, in order to avoid these defects appearing, or of treating the surface afterwards, in order to eliminate them.

### BRIEF SUMMARY

The present disclosure overcomes all or some of the aforementioned drawbacks. In particular, it relates to a process for fabricating a semiconductor structure, the working layer of which, made of monocrystalline silicon carbide and transferred onto a carrier substrate made of silicon carbide, via a bonding interface, has excellent electrical properties. The process according to the disclosure furthermore makes it possible to improve the vertical conduction performance of the semiconductor structure, while at the same time proposing simple implementation steps.

The disclosure relates to a process for fabricating a semiconductor structure comprising the following steps:
a) providing a donor substrate made of monocrystalline silicon carbide and a carrier substrate made of silicon carbide,
b) preparing a working layer to be transferred, comprising:
   implanting light species in the donor substrate on a front face, in order to form a damage profile, which can notably be measured by means of Rutherford backscattering spectrometry, the profile having a main peak of depth defects defining a buried brittle plane and a secondary peak of defects defining a damaged surface layer,
   removing the damaged surface layer by means of chemical etching and/or by means of chemical-mechanical polishing of the front face of the donor substrate, in order to form a new front surface of the donor substrate,
   the buried brittle plane delimiting, with the front surface of the donor substrate, the working layer to be transferred, which has a thickness of between 50 nm and 1400 nm,
c) joining the donor substrate, on the side of the front surface, and the carrier substrate by means of molecular adhesion, in order to form an assembly bonded along a bonding interface; and
d) separating along the buried brittle plane, leading to transferring the working layer onto the carrier substrate, in order to form the semiconductor structure.

According to other advantageous and non-limiting features of the disclosure, taken alone or in any technically feasible combination:
the removal of step b) results in between 5 nm and 200 nm, preferably between 30 nm and 50 nm, being stripped away;
the material of the carrier substrate is monocrystalline or polycrystalline;
the light species are hydrogen ions, implanted with an energy of between 30 keV and 210 keV and at a dose of between 1×10¹⁶/cm² and 5×10¹⁷/cm²;
the fabrication process comprises a finishing step e) applied to the semiconductor structure resulting from step d), step e) involving a heat treatment at a temperature of between 1300° C. and 1700° C.;
step e) comprises a chemical-mechanical smoothing treatment of a free surface of the working layer;
step c) comprises forming at least one additional layer on the front surface of the donor substrate and/or on a front face of the carrier substrate, prior to the joining by means of molecular adhesion; and the bonded assembly, obtained after the joining by means of molecular adhesion, comprises the additional layer between the donor substrate and the carrier substrate, the layer being adjacent to the bonding interface or including the latter;
the at least one additional layer comprises a material chosen from among silicon, tungsten, carbon and titanium;
the process further comprises steps of creating at least one high-voltage microelectronic component on the semiconductor structure.

The disclosure also relates to a high-voltage microelectronic component created on a semiconductor structure obtained by means of the fabrication process as mentioned above.

### BRIEF DESCRIPTION OF THE DRAWINGS

Other features and advantages of the disclosure will become apparent from the following detailed description, with reference to the accompanying figures:

FIG. 1 shows a semiconductor structure created according to a fabrication process in accordance with the disclosure;

FIGS. 2A, 2B, 2B′, 2C, 2D and 2E show steps of a fabrication process in accordance with the disclosure;

FIG. 3 shows Rutherford backscattering spectrometry (RBS) measurements of a virgin donor substrate and of a donor substrate having undergone the implantation of light species of step d) of the fabrication process in accordance with the disclosure, respectively;

FIG. 4 shows I(V) curves of current as a function of applied voltage, which is measured from two electrodes created on a semiconductor structure, the current path crossing the bonding interface of the structure: Panel (a) for a semiconductor structure of the prior art and Panel (b) for a semiconductor structure in accordance with the disclosure;

FIG. 5 shows Panel (a) a transmission electron microscopy (TEM) image of a final semiconductor structure not in accordance with the disclosure, and Panel (b) an image, obtained by means of SSRM resistance measurement, of a final semiconductor structure not in accordance with the disclosure.

The same references in the figures may be used for elements of the same type. The figures are schematic representations that, for the sake of legibility, are not to scale. In particular, the thicknesses of the layers along the z-axis are not to scale with respect to the lateral dimensions along the x- and y-axes, and the relative thicknesses of the layers with respect to one another are not represented in the schematic figures.

The various possibilities (variants and embodiments illustrated and/or detailed in the description to follow) must be understood as not being mutually exclusive and can be combined with one another.

### DETAILED DESCRIPTION

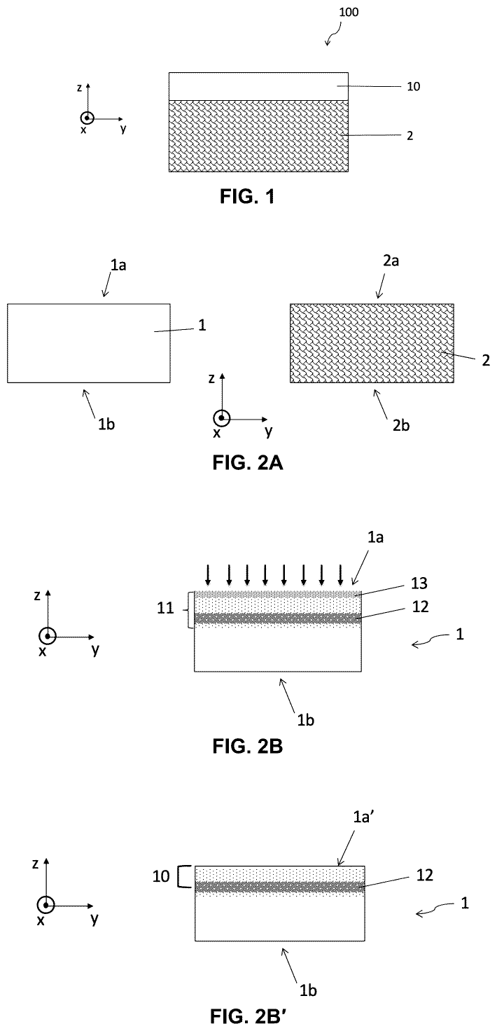

The disclosure relates to a process for fabricating a semiconductor structure 100 comprising a working layer 10 made of monocrystalline silicon carbide (SiC) transferred onto a carrier substrate 2 (FIG. 1). The carrier substrate 2 can be formed from monocrystalline or polycrystalline silicon carbide.

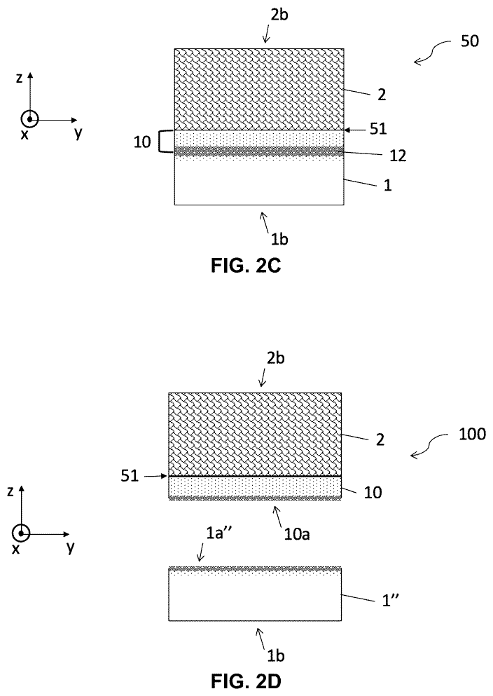

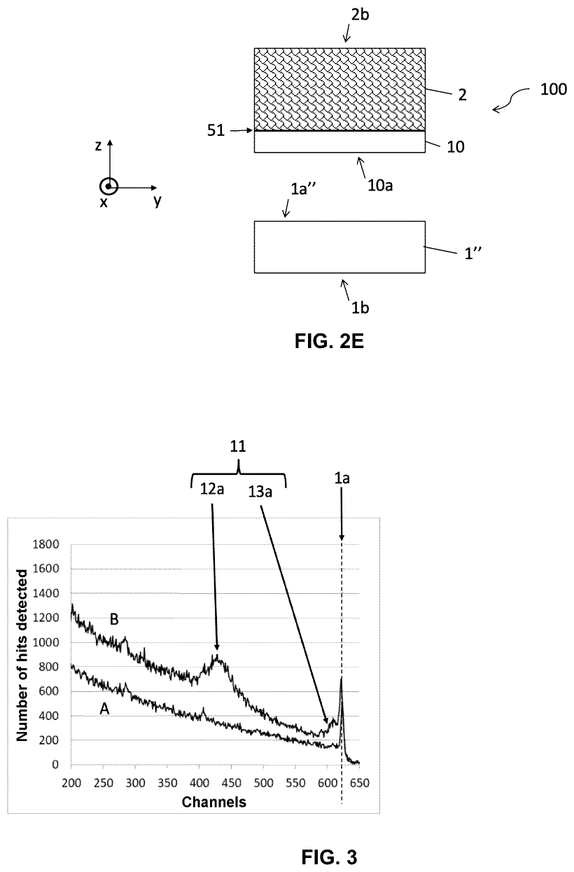

The fabrication process first comprises a step a) of providing a donor substrate 1 made of monocrystalline silicon carbide and a carrier substrate 2 made of monocrystalline or polycrystalline silicon carbide (FIG. 2A). These two initial substrates 1, 2 are preferably in the form of wafers (in the plane (x, y)) with a diameter of 100 mm, 150 mm or 200 mm, and with a thickness (along the z-axis) typically of between 300 and 800 microns. They each have a front face 1a, 2a and a rear face 1b, 2b. The surface roughness of the front faces 1a, 2a is advantageously chosen to be less than 1 nm RMS measured by means of atomic force microscopy (AFM) on a scan of 20 microns×20 microns.

The donor substrate 1 can, for example, be of 4H or 6H polytype, and have doping of n or p type. Later on in the process, the working layer 10 of the semiconductor structure 100 will be detached from the donor substrate 1: the latter must therefore have the mechanical, electrical and crystallographic properties required for the targeted application.

According to one particular embodiment, the donor substrate 1 comprises an initial substrate on which a donor layer has been produced by means of epitaxy. The epitaxial growth step is performed such that the donor layer has a crystal defect density that is lower than that of the initial substrate. As the working layer 10 is, in this case, detached from the donor layer, the initial substrate does not need as high a level of quality as the donor layer.

The carrier substrate 2 must meet the specifications on mechanical strength and potentially the specifications on electrical properties allowing good vertical electrical conduction for the operation of vertical power components that are created on and in the final semiconductor structure 100.

The fabrication process then comprises a step b) consisting in preparing the working layer 10 to be transferred. This step firstly comprises implanting light species in the donor substrate 1 (or in the donor layer, when the latter is present) on the front face 1a, in order to form an implantation profile of the light species and a damage profile 11 (FIG. 2B). These two profiles are almost superposed, the first corresponding to the concentration by depth of the implanted species, the other corresponding to the defects generated in the crystal lattice of the SiC material of the donor substrate 1 when the species penetrate in.

The damage profile 11 can notably be measured by means of Rutherford backscattering spectrometry (or RBS). As is well known, RBS is used to determine the structure and the composition of a material by analyzing the backscattering of a high-energy ion beam striking the material. It makes it possible in this instance to reveal regions of defects present in the implanted SiC crystal lattice of the donor substrate 1.

The curve A in FIG. 3 corresponds to an RBS measurement of the donor substrate 1 before implanting light species: the RBS profile is flat (with the exception of the very narrow peak detected on the front face 1a that appears on all the measured samples and that is, therefore, not distinctive).

The curve B of FIG. 3 corresponds to an RBS measurement of the donor substrate 1 after implanting light species. The damage profile 11 has a main peak 12a of depth defects (which is substantially superposed on the peak of the concentration of the implanted light species), defining a buried brittle plane 12. The damage profile 11 also has a secondary peak 13a of defects defining a damaged surface layer 13.

The implanted light species are preferably hydrogen, helium or these two species co-implanted. With reference to the SMART CUT® process, mentioned in the introduction, these light species will form, at and/or in the vicinity of the main peak 12a, microcavities distributed in a thin layer that is parallel to the front face 1a of the donor substrate 1, i.e., parallel to the plane (x,y) in the figures. This thin layer is called the buried brittle plane 12, for the sake of simplicity.

The implantation energy of the light species is chosen so that a determined depth in the donor substrate 1 is reached. Typically, hydrogen ions are implanted with an energy of between 30 keV and 210 keV, and at a dose of between 1×10¹⁶/cm² and 5×10¹⁷/cm², in order to form a buried brittle plane 12 at a depth of between 100 nm and 1500 nm.

The secondary peak 13a, which is visible in FIG. 3, extends from the front face 1a of the donor substrate 1 to a variable depth, of between 10 nm and 100 nm, essentially depending on the implantation conditions (energy, dose, temperature, etc.). This damaged surface layer 13 can notably comprise localized crystal defects, extended defects (dislocations, etc.), or species that are not intentionally introduced, other than the implanted light species. The surface roughness of the donor substrate 1, on the front face 1a having undergone implantation, is not affected and remains substantially similar to the initial roughness, typically less than 1 nm RMS.

After ionically implanting the light species, step b) of preparing the working layer 10 comprises removing the damaged surface layer 13 by means of chemical etching and/or by means of chemical-mechanical polishing of the front face 1a of the donor substrate 1 (FIG. 2B′).

The chemical etching is advantageously dry, for example reactive-ion etching based on O2/SF6/Ar/F gas. The chemical-mechanical polishing can be carried out using polishing solutions (slurry) with alumina- or diamond-based nano-abrasives, and conventional fabrics of polyurethane or thermoplastic foam type.

Whatever technique is implemented, the removal carried out in step b) results in between 5 nm and 200 nm, preferably between 20 nm and 100 nm, and more preferably between 30 nm and 50 nm, of SiC being stripped away. After this material is stripped away, a new front surface 1a′ of the donor substrate 1 is formed.

The aim is to remove the whole damaged surface layer 13, while at the same time preserving good uniformity of the working layer 10 to be transferred: specifically, the working layer 10 is delimited by the buried brittle plane 12 and the new front surface 1a′ of the donor substrate 1, after stripping. A non-uniformity of less than +/−20% of the thickness of the working layer 10 is targeted. The working layer 10 to be transferred typically has a thickness of between 50 nm and 1400 nm.

The fabrication process then comprises a step c) including joining the donor substrate 1, on the side of the new front surface 1a′, and the carrier substrate 2, on the side of its front face 2a, by means of molecular adhesion, in order to form an assembly 50 bonded along a bonding interface 51 (FIG. 2c).

As is well known per se, direct bonding by means of molecular adhesion does not require an adhesive material, as bonds are established at the atomic scale between the joined surfaces. Several types of bonding by means of molecular adhesion exist, which differ notably in the temperature, pressure, atmosphere conditions or treatments prior to bringing the surfaces into contact. Mention may be made of bonding at room temperature with or without prior plasma activation of the surfaces to be joined, atomic diffusion bonding (ADB), surface activated bonding (SAB), etc.

The joining step c) can comprise, prior to bringing the faces to be joined into contact, conventional sequences of chemical cleaning (for example, RCA cleaning) and of surface activation (for example, by means of oxygen or nitrogen plasma) or other surface preparations (such as scrubbing), which are likely to promote the quality of the bonding interface 51 (low defect density, high adhesion energy).

According to a first embodiment, the new front surface 1a′ of the donor substrate 1 and the front face 2a of the carrier substrate 2 are joined directly, as illustrated in FIG. 2C.

According to a second embodiment, step c) comprises forming at least one additional layer (which is not shown) on the new front surface 1a′ of the donor substrate 1 and/or on the front face 2a of the carrier substrate 2, prior to the joining by means of molecular adhesion. The at least one additional layer can comprise a material such as silicon, tungsten, carbon or titanium, advantageously chosen to promote vertical electrical conduction in the final semiconductor structure 100. The intermediate layer is furthermore likely to promote bonding by means of molecular adhesion, notably by erasing residual roughness or surface defects present on the faces to be joined. It can undergo conventional planarizing or smoothing treatments, in order to reach a roughness of less than 1 nm RMS, or even less than 0.5 nm RMS, which promotes bonding; it can also undergo preparatory treatments such as those previously mentioned (cleaning, activation, etc.). The thickness of the additional layer is preferably chosen to be between 0.5 nm and 50 nm.

The fabrication process according to the disclosure finally comprises a step d) of separating along the buried brittle plane 12, leading to transferring the working layer 10 onto the carrier substrate 2, in order to form the semiconductor structure 100 (FIG. 2D).

The separation along the buried brittle plane 12 is usually carried out by applying a heat treatment at a temperature of between 800° C. and 1200° C. Such a heat treatment causes cavities and microcracks to develop in the buried brittle plane 12, and them to be pressurized by the light species present in gaseous form, until a fracture propagates along the brittle plane 12. Alternatively, or jointly, mechanical stress can be applied to the bonded assembly 50, and, in particular, to the buried brittle plane 12, so as to propagate or assist in mechanically propagating the fracture leading to the separation. As a result of this separation, the semiconductor structure 100 comprising the carrier substrate 2 and the transferred working layer 3 made of monocrystalline SiC, on the one hand, and the remainder 1″ of the donor substrate with new front surface 1a″, on the other hand, are obtained. The level and the type of doping of the working layer 10 are defined by the choice of the properties of the donor substrate 1 or can be adjusted subsequently via the known techniques for doping semiconductor layers.

The free surface 10a of the working layer 10 is usually rough after separation: for example, it has a roughness of between 5 nm and 100 nm RMS (AFM, 20 micron×20 micron scan). Cleaning and/or smoothing steps can be applied in order to restore a good surface finish (typically, roughness of less than a few angstroms RMS on a 20 micron×20 micron AFM scan).

This is notably the object of the finishing step e), preferably included in the fabrication process according to the disclosure. This step, applied to the semiconductor structure 100 resulting from step d), can comprise a chemical-mechanical smoothing (CMP) treatment of the free surface 10a of the working layer 10. Stripping away between 50 nm and 300 nm makes it possible to restore the surface finish of the layer 10 effectively.

Step e) can also comprise a heat treatment at a temperature of between 1300° C. and 1700° C. Such a heat treatment is applied in order to clear the residual light species from the working layer 10 and in order to promote the rearrangement of the crystal lattice of the working layer 10.

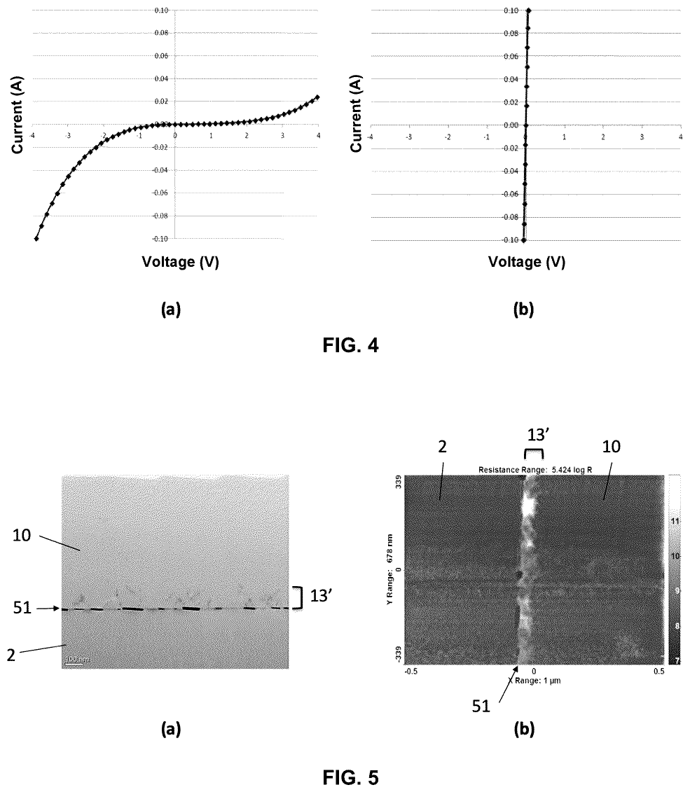

As mentioned in the introduction, good electrical characteristics of the working layer 10, which is conventionally transferred by implanting light species, are difficult to obtain if the finishing heat treatment remains at a temperature of less than 1800° C. In the example of FIG. 4, Panel (a), the semiconductor structure not in accordance with the disclosure is formed from a working layer made of monocrystalline SiC (typical resistivity of around 20 mohm.cm) and transferred onto a carrier substrate (typical resistivity of around 50 mohm.cm) via an additional metal layer; the conditions under which implantation in the donor substrate took place were the following: 130 keV, 6*10¹⁶ H/cm², and a finishing heat treatment was performed at 1700° C. for 1 hour. It may be seen that the I(V) behavior of this structure is not ohmic.

In the process according to the disclosure, this heat treatment can be carried out at a temperature of less than or equal to 1700° C., or even of between 1400° C. and 1500° C. Indeed, perfectly ohmic behavior of the working layer 10 and of the bonding interface 51 of the semiconductor structure 100 that is created in accordance with the present disclosure is observed on the I(V) curve in FIG. 4, Panel (b). The semiconductor structure is formed from a working layer 10 made of monocrystalline SiC (typical resistivity of around 20 mohm.cm) and transferred onto a carrier substrate 2 (typical resistivity of around 20 mohm.cm) via an additional metal layer (stack comparable to the structure according to the prior art, mentioned above with reference to FIG. 4, Panel (a)); the conditions under which implantation (step b)) in the donor substrate 1 took place were 130 keV, 6*10¹⁶ H/cm², the removal (step b)) of the damaged surface layer 13 consisted in stripping away 50 nm by means of CMP and the heat treatment of step e) was performed at 1700° C. for 1 hour.

Note that an annealing up to 1900° C. could obviously be performed but these very high temperatures are not necessary for restoring the electrical qualities of the thin layer 10 in the process in accordance with the disclosure.

The applicant has identified that removing the damaged surface layer 13, generated during the ionic implantation of step b) of preparing the working layer 10 to be transferred from the donor substrate 1, was critical for obtaining, after transfer, excellent electrical properties of the thin layer 10 and of the semiconductor structure 100 in general, while staying at reasonable finishing heat treatment temperatures.

This damaged surface layer 13, if it is not removed during step b) of the process according to the disclosure, is responsible for residual defects 13′ in the thin layer of the final semiconductor structure, as illustrated in FIG. 5, Panel (a): the residual defects 13′, which stay present despite heat treatments at high temperatures up to 1700° C., or even up to 1900° C., are observed in this transmission electron microscopy (TEM) image. An SSRM (scanning spreading resistance microscopy, a technique for measuring resistance by means of scanning by a tip of an atomic force microscope) measurement, which indicates a region of greater resistivity near the bonding interface 51 of the semiconductor structure, correlated with the region of the residual defects 13′, may also be seen in FIG. 5, Panel (b). The residual defects 13′ that are present in the working layer 10, near the bonding interface 51, when the damaged surface layer 13 is not removed before joining, are the cause of the non-ohmic electrical behavior of the semiconductor structure that is observed in FIG. 4, Panel (a).

The fabrication process in accordance with the disclosure provides for removing the damaged surface layer 13, generated by implanting light species in the donor substrate 1, and thus ensures the high quality of the working layer 10 in the final semiconductor structure 100 and its electrical behavior of ohmic type.

The disclosure also relates to one (or more) high-voltage microelectronic component(s), such as, for example, Schottky diodes, MOSFETs, etc., created on and/or in a semiconductor structure 100 resulting from the previously described fabrication process. Conventional steps of creating components can be implemented, the semiconductor structure 100 being perfectly compatible with microelectronic techniques and lines.

Of course, the disclosure is not limited to the embodiments and to the examples that have been described, and variant embodiments can be added to it without departing from the scope of the invention as defined by the claims.

1. A method of fabricating a semiconductor structure, the method comprising:
a) providing a donor substrate of monocrystalline silicon carbide and a carrier substrate of silicon carbide;
b) preparing a working layer to be transferred, comprising:
implanting light species in the donor substrate on a front face to form a damage profile, the damage profile having a main peak of depth defects defining a buried brittle plane and a secondary peak of defects defining a damaged surface layer,
removing the damaged surface layer by way of chemical etching and/or by way of chemical-mechanical polishing of the front face of the donor substrate to form a new front surface of the donor substrate, the buried brittle plane delimiting, with the new front surface of the donor substrate, the working layer to be transferred, the working layer to be transferred having a thickness of between 50 nm and 1400 nm;
c) joining the donor substrate, on a side of the new front surface, and the carrier substrate by way of molecular adhesion to form an assembly bonded along a bonding interface; and
d) separating along the buried brittle plane, leading to transferring the working layer onto the carrier substrate to form the semiconductor structure.

2. The method of claim 1, wherein the removing of the damaged surface layer results in between 5 nm and 200 nm being stripped away.

3. The method of claim 1, wherein the carrier substrate comprises monocrystalline or polycrystalline material.

4. The method of claim 1, wherein the light species are hydrogen ions, implanted with an energy of between 30 keV and 210 keV and at a dose of between 1×10¹⁶/cm² and 5×10¹⁷/cm².

5. The method of claim 1, further comprising heat treating the semiconductor structure at a temperature of between 1300° C. and 1700° C. after the separating along the buried plane to form the semiconductor structure.

6. The method of claim 5, further comprising applying a chemical-mechanical smoothing treatment to a free surface of the working layer after the separating along the buried plane to form the semiconductor structure.

7. The method of claim 1, wherein:
the joining of the donor substrate and the carrier substrate further comprises forming at least one additional layer on the front surface of the donor substrate and/or on a front face of the carrier substrate, prior to the joining by way of molecular adhesion; and
the bonded assembly, obtained after the joining by way of molecular adhesion, comprises the at least one additional layer between the donor substrate and the carrier substrate, the at least one additional layer being adjacent to or including the bonding interface.

8. The method of claim 7, wherein the at least one additional layer comprises at least one material chosen from among the group including silicon, tungsten, carbon or titanium.

9. The method of claim 1, further comprising forming at least one high-voltage microelectronic component on the semiconductor structure.

10. The method of claim 2, wherein the removing of the damaged surface layer results in between 30 nm and 50 nm being stripped away.

11. The method of claim 2, wherein the carrier substrate comprises monocrystalline or polycrystalline material.

12. The method of claim 11, wherein the light species are hydrogen ions, implanted with an energy of between 30 keV and 210 keV and at a dose of between 1×10¹⁶/cm² and 5×10¹⁷/cm².

13. The method of claim 12, further comprising heat treating the semiconductor structure at a temperature of between 1300° C. and 1700° C. after the separating along the buried plane to form the semiconductor structure.

14. The method of claim 13, further comprising applying a chemical-mechanical smoothing treatment to a free surface of the working layer after the separating along the buried plane to form the semiconductor structure.

15. The method of claim 14, wherein:
the joining of the donor substrate and the carrier substrate further comprises forming at least one additional layer on the front surface of the donor substrate and/or on a front face of the carrier substrate, prior to the joining by way of molecular adhesion; and
the bonded assembly, obtained after the joining by way of molecular adhesion, comprises the at least one additional layer between the donor substrate and the carrier substrate, the at least one additional layer being adjacent to or including the bonding interface.

16. The method of claim 15, wherein the at least one additional layer comprises at least one material chosen from among the group including silicon, tungsten, carbon or titanium.

17. The method of claim 16, further comprising forming at least one high-voltage microelectronic component on the semiconductor structure.
